(19) United States
(12) Patent Application Publication
(10) Pub. No.: US 2008/0068818 A1
(43) Pub. Date: Mar. 20, 2008

(54) METHOD AND APPARATUS FOR PROVIDING ULTRA-WIDE BAND NOISE ISOLATION IN PRINTED CIRCUIT BOARDS

(76) Inventor: Jinwoo Choi, Austin, TX (US)

Correspondence Address: DILLON & YUDELL LLP, 8911 N. CAPITAL OF TEXAS HWY.,, SUITE 2110, AUSTIN, TX, 78759, US

(21) Appl. No.: 11/533,043

(22) Filed: Sep. 19, 2006

(51) Int. Cl. H05K 9/00

(52) U.S. Cl. 361/818

(57) ABSTRACT

A printed circuit board having ultra-wide band noise isolation is disclosed. The printed circuit board includes a first metal plane, a second metal plane, and a dielectric layer formed between the first and second metal planes. Two groups of noise isolation structures are formed within one of the metal planes, and the noise isolation structures in each group have a different size than those of the other group.

### BACKGROUND OF THE INVENTION

1. Technical Field

The present invention relates to printed circuit boards in general, and more particularly, to a method and apparatus for providing noise isolation in printed circuit boards. Still more particularly, the present invention relates to a method and apparatus for providing ultra-wide band noise isolation in printed circuit boards.

2. Description of Related Art

Simultaneous switching noise (SSN) refers to voltage glitches generated in a digital system due to rapid changes in current caused by many circuits in the digital system switching at the same time. Since a pair of power/ground planes in a printed circuit board behave like a parallel-plate waveguide at high frequencies, SSN generated by switching digital circuits can be coupled to noise sensitive circuits to cause a system failure.

The conventional method of suppressing SSN in a printed circuit board is to connect decoupling capacitors, which are expected to behave like short circuits at high frequencies, between power and ground planes of the printed circuit board in order to lower the impedance of a power distribution network and to supply current bursts for fast switching circuits. However, decoupling capacitors become close to short circuits only around their self-resonant frequency and behave more like resistor-inductor-capacitor (RLC) resonant circuits otherwise. In addition, the parasitic inductances of mounting pads and the leads of decoupling capacitors strongly limit their ability to mitigate SSN. In fact, due to parasitic inductance, decoupling capacitors are not even effective at switching frequencies above one gigahertz.

Since decoupling capacitors are not effective at switching frequencies greater than one gigahertz, alternative isolation techniques, such as split planes with multiple power supplies, split planes and ferrite beads with a single power supply, split power islands, etc., have been utilized to suppress SSN at switching frequencies greater than one gigahertz in a printed circuit board. However, there are two fundamental problems to those solutions, namely, poor isolation in the −20 dB to −60 dB range above one gigahertz and narrow band capabilities.

Consequently, it would be desirable to provide an improved method and apparatus for providing SSN isolation in printed circuit boards.

### SUMMARY OF TILE INVENTION

In accordance with a preferred embodiment of the present invention, a printed circuit board includes a first metal plane, a second metal plane, and a dielectric layer formed between the first and second metal planes. Two groups of noise isolation structures are formed within one of the metal planes, and the noise isolation structures in each group have a different size from those of the other group. In one embodiment, the noise isolation structure includes a center and four flanges. The center has four edges and four corners. The first flange is located on the first edge at the first corner. The second flange is located on the second edge at the second corner. The third flange is located on the third edge at the fourth corner. The fourth flange is located on the fourth edge at the first corner.

All features and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is a top view of a noise isolation structure, in accordance with a preferred embodiment of the present invention;

FIG. 2 is a top view of a printed circuit board having noise isolation structures of different sizes, in accordance with a preferred embodiment of the present invention;

FIG. 3 is an isomeric view of a printed circuit board having multiple noise isolation structures, in accordance with a preferred embodiment of the present invention; and

FIG. 4 is a graph of a measured transmission coefficient between two ports in the printed circuit board from FIG. 2.

### DETAILED DESCRIPTION OF A PREFERRED EMBODIMENT

The present invention employs different sizes of alternating impedance electromagnetic bandgap (AI-EBG) structures to achieve noise isolation over an ultra-wide frequency range (i.e., above 10 gigahertz).

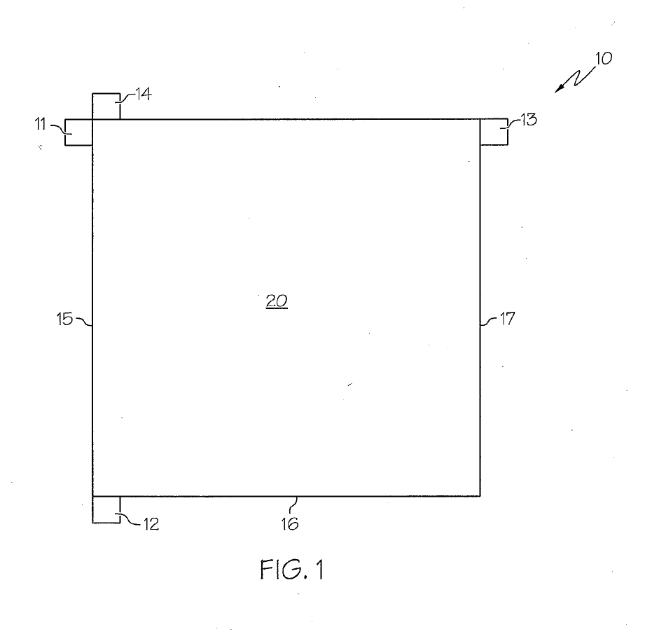

Referring now to the drawings and in particular to FIG. 1, there is depicted a top view of an AI-EBG structure 10, in accordance with a preferred embodiment of the present invention. As shown, AI-EBG structure 10 is a rectangular lattice having a center 20 and four flanges 11-14. Center 20 can have a rectangular or square shape. Flanges 11-14 can also be in rectangular or square shapes. Center 20 includes four edges 15-18 and four corners a-d. For the present embodiment, flange 11 is located on edge 15 at corner a, flange 12 is located on edge 16 at corner b, flange 13 is located on edge 17 at corner d, and flange 14 is located on edge 18 at corner a. It is understood by those skilled in the art that the above-mentioned flange arrangement is simply exemplary, and other flange arrangements are also applicable.

For Al-EBG structure 10, flanges 11-14 introduce additional inductance while center 20 and a corresponding solid metal plane within a printed circuit board form a capacitor. The locations of flanges 11-14 on edges 15-18 of AI-EBG structure 10 are optimized to ensure maximum wave destructive interference, which results in excellent isolation characteristics within a stopband range.

In filter theory, the overall effect of cascaded filters is a superposition of effect of the individual filters. Similarly, since AI-EBG structure 10 behaves like a low-pass filter, and the size of center 20 mainly determines the stopband frequency range for AI-EBG structure 10, it is possible to design a printed circuit board with AI-EBG structures of different sizes to provide noise isolation over an ultra-wide frequency range.

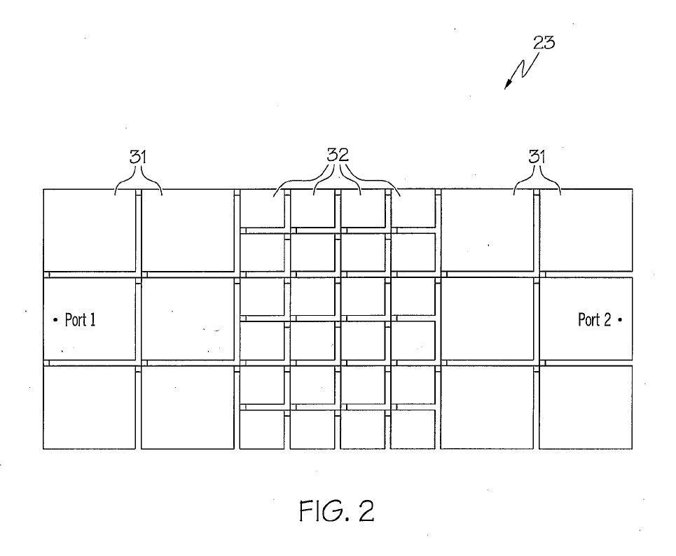

With reference now to FIG. 2, there is illustrated a top view of a printed circuit board having AI-EBG structures of different sizes, in accordance with a preferred embodiment of the present invention. As shown, a printed circuit board 23 includes AI-EBG structures of two different sizes, namely, type I structures 21 and type II structures 22. For the present embodiment, the entire size of printed circuit board 23 is approximately 9.5 cm×4.7 cm, the size of type I structures 21 is approximately 1.5 cm×1.5 cm, and the size of type II structure 22 is approximately 0.7 cm×0.7 cm. It is understood by those skilled in the art that the sizes of type I structures 21 and type II structures 22 can be changed if there is a change in the dielectric material because the frequency stopband range depends on the dielectric constant of the dielectric material. For type I structures 21 and type II structures 22, the sizes of horizontal flanges (i.e., flanges 11 and 13 in FIG. 1) are approximately 0.1 cm×0.05 cm, and the sizes of vertical flanges (i.e., flanges 12 and 14 in FIG. 1) are approximately 0.05 cm×0.1 cm. Type I structures 21 and type II structures 22 are connected to each other via their corresponding flanges.

Printed circuit board 23 includes two ports. For the present embodiment, a port 1 is placed at (0.3 cm, 1.95 cm) and a port 2 is placed at (9.2 cm, 1.95 cm) with the origin (0, 0) located at the bottom left corner of printed circuit board 23.

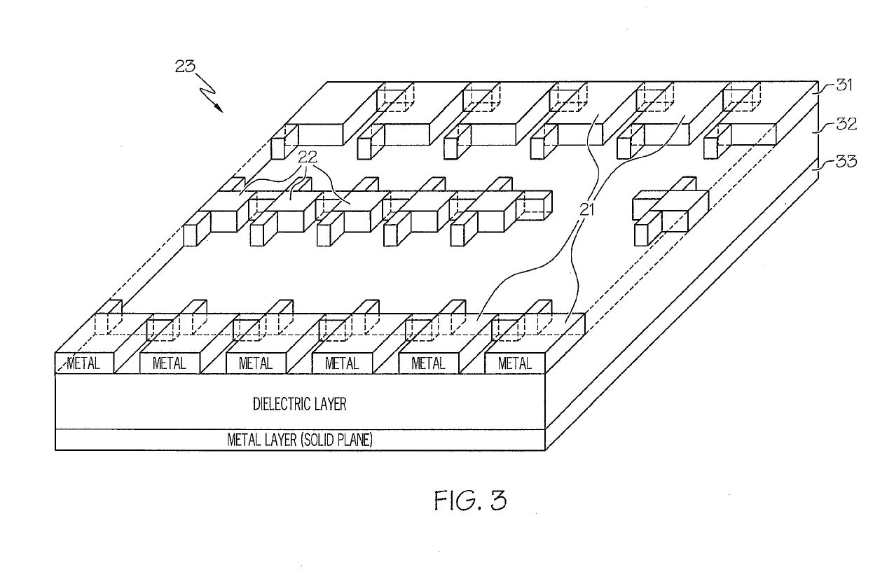

Referring now to FIG. 3, there is illustrated an isomeric view of printed circuit board 23 having multiple AI-EBG structures, in accordance with a preferred embodiment of the present invention. As shown, printed circuit board 23 includes a first metal layer 31 and a second metal layer 33 separated by a dielectric layer 32. Dielectric layer 32 is made of FR4 Epoxy Laminate having a relative permittivity of 4.4 and a thickness of 8 mils. It is understood by those skilled in the art that different types of dielectric material can be utilized for providing a different stopband frequency range. Each of first metal layer 31 and second metal layer 33 is made of copper having a conductivity of 5.8×10⁷ s/m and a thickness of 35 μm. Although first metal layer 31 and second metal layer 33 are made of copper, it is understood by those skilled in the art that other types of metal can also be utilized.

Printed circuit board 23 along with type I structures 21 and type II structures 22 can be fabricated using a standard printed circuit board fabrication process that is well-known to those skilled in the relevant art. Type I structures 21 and type II structures 22 can be formed by etching first metal layer 31. Type I structures 21 and type II structures 22 are interconnected by metal lines to form a distributed inductor-capacitor (LC) network.

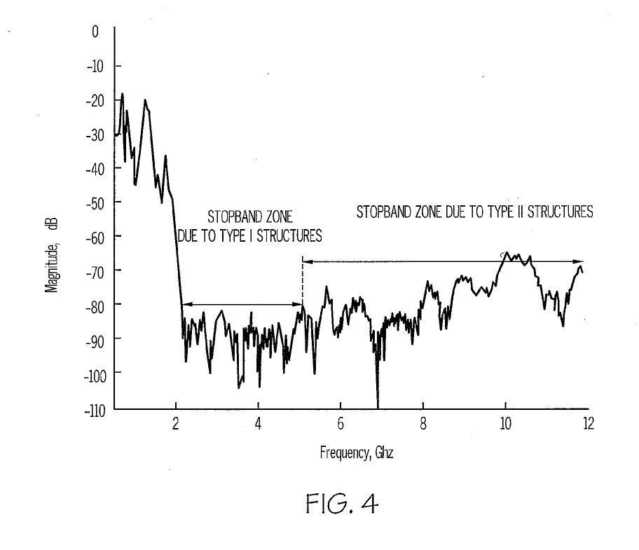

With reference now to FIG. 4, there is depicted a graph illustrating a measured transmission coefficient (S₂₁) between port 1 and port 2 in printed circuit board 23. As shown, printed circuit board 23 has an excellent isolation from 2 gigahertz to 12 gigahertz, which is over 10 gigahertz. Specifically, type I structures 21 from FIG. 3 make a first stopband that ranges from 2 to 5 gigahertz and type II structures 22 from FIG. 3 make a second stopband that ranges from 5 to 12 gigahertz. S₂₁ reached the sensitivity limit (−80 dB to −100 dB) in the frequency range from 2 gigahertz to 8 gigahertz. This result is better than those achieved by the prior art noise isolation structures in terms of isolation level and stopband width. Moreover, printed circuit board 23 does not need an additional metal patch layer and blind vias, which makes it more desirable for printed circuit board applications.

As has been described, the present invention provides a method and apparatus for providing ultra-wide band noise isolation in printed circuit boards.

While the invention has been particularly shown and described with reference to a preferred embodiment, it will be understood by those skilled in the art that various changes in form and detail may be made therein without departing from the spirit and scope of the invention.

1. A printed circuit board capable of providing ultra-wide band noise isolation, said printed circuit board comprising:
a first metal plane, a second metal plane, and a dielectric layer formed between said first and second metal planes; and
a set of type I noise isolation structures having a first size and a set of type II noise isolation structures having a second size, both formed within one of said metal planes, wherein said type I noise isolation structures provide noise isolation over a first frequency range, and said type II noise isolation structures provide noise isolation over a second frequency range.

2. The printed circuit board of claim 1, wherein one of said noise isolation structures includes
a center having a first, second, third and fourth edges, and a first, second, third and fourth corners;
a first flange located on said first edge at said first corner;
a second flange located on said second edge at said second corner;
a third flange located on said third edge at said fourth corner; and
a fourth flange located on said fourth edge at said first corner.

3. The printed circuit board of claim 1, wherein said type I noise isolation structures are approximately 1.5 cm² in size and said type II noise isolation structures are approximately 0.7 cm² in size.

4. The printed circuit board of claim 1, wherein said metal planes are made of copper.

5. The printed circuit board of claim 1, wherein said dielectric layer is made of FR4 Epoxy Laminate.

6. A method of providing ultra-wide band noise isolation in a printed circuit board, said method comprising:
embedding a dielectric layer between a first metal plane and a second metal plane of a printed circuit board; and
etching a set of type I noise isolation structures having a first size and a set of type II noise isolation structures having a second size within one of said metal planes of said printed circuit board, wherein said type I noise isolation structures provide noise isolation over a first frequency range, and said type II noise isolation structures provide noise isolation over a second frequency range.

7. The method of claim 6, wherein one of said noise isolation structures includes
a center having a first, second, third and fourth edges, and a first, second, third and fourth corners;
a first flange located on said first edge at said first corner;
a second flange located on said second edge at said second corner;
a third flange located on said third edge at said fourth corner; and
a fourth flange located on said fourth edge at said first corner.

8. The method of claim 6, wherein said type I noise isolation structures are approximately 1.5 cm² in size, and said type II noise isolation structures are approximately 0.7 cm² in size.

9. The method of claim 6, wherein said metal planes are made of copper.

10. The method of claim 6, wherein said dielectric layer is made of FR4 Epoxy Laminate.

11-12. (canceled)
